(19) United States
(12) Patent Application Publication
(10) Pub. No.: US 2018/0090421 A1
(43) Pub. Date: Mar. 29, 2018

(54) LONG-LASTING WETTABLE FLANKS

(71) Applicant: SEMICONDUCTOR COMPONENTS INDUSTRIES, LLC, Phoenix, AZ (US)

(72) Inventors: Nam Khong THEN, Seremban (MY); Hui Min LER, Seremban (MY); Phillip CELAYA, Gilbert, AZ (US); Chee Hiong CHEW, Seremban (MY)

(73) Assignee: SEMICONDUCTOR COMPONENTS INDUSTRIES, LLC, Phoenix, AZ (US)

(21) Appl. No.: 15/278,203

(22) Filed: Sep. 28, 2016

(51) Int. Cl. H01L 23/495; H01L 21/48

(52) U.S. Cl. CPC H01L 23/49541; H01L 23/49517; H01L 21/4853; H01L 23/49582

(57) ABSTRACT

A method for plating package leads, in some embodiments, comprises: providing a package having a lead electrically coupled to a tie bar; singulating said lead; electroplating said singulated lead using the tie bar; and singulating said tie bar.

### BACKGROUND

Semiconductor packages contain electrical components—for example, integrated circuits or discrete devices—that perform any of a variety of functions. The packages are typically encapsulated in a non-conductive material to protect the electrical components from external mechanical or electrical damage. A package further includes electrical terminals that provide electrical pathways between the electrical component housed within the package and electronic devices external to the package (e.g., a printed circuit board). By coupling the electrical terminals to such an external electronic device, the electrical component inside the package can communicate with the electronic device external to the package.

The electrical connection between the package terminals and an external electronic device is usually made with solder or a similar conductive substance. Wetting the package terminals with solder can sometimes be difficult, particularly when the terminals are corroded. For such reasons, the package terminals—typically made of copper—are plated with a substance that is more resistant to corrosion, such as tin.

Common plating techniques, such as immersion, are suboptimal because the plating thickness achieved is insufficient. In most cases, the plating is so thin that the plating substance (e.g., tin) migrates into the terminal itself and lowers the probability of successful wetting when coupling the package to an external electronic device. This problem is particularly significant when packages are stored for extended periods of time, because the length of storage time relates directly to the degree of migration.

### SUMMARY

At least some embodiments are directed to method for plating package leads, comprising: providing a package having a lead electrically coupled to a tie bar; singulating said lead; electroplating said singulated lead using the tie bar; and singulating said tie bar. One or more such embodiments may be supplemented using one or more of the following concepts, in any order and in any combination: wherein singulating the lead comprises causing an end of the lead to be flush with a side surface of the package; wherein said singulating comprises punching; wherein said singulating comprises sawing; wherein said electroplating comprises electroplating the lead with tin; wherein said electroplating results in said lead having a plating at least 7 microns thick; wherein said electroplating comprises applying a current to the tie bar; wherein applying said current to the tie bar results in another package lead being electroplated, said lead and the another lead electrically coupled to each other; wherein providing the package comprises electrically coupling said lead to said tie bar; wherein said package comprises a second lead electrically coupled to said lead and a third lead electrically isolated from the lead and the second lead, and wherein applying current to the tie bar to electroplate the lead also results in electroplating the second lead but not the third lead; further comprising applying a current to a second tie bar coupled to the third lead to electroplate the third lead.

At least some embodiments are directed to a method, comprising: providing a package having first, second and third electrical terminals, said first and second electrical terminals electrically coupled to each other and to a first tie bar, said third electrical terminal electrically isolated from the first and second electrical terminals and electrically coupled to a second tie bar; singulating the first, second and third electrical terminals; applying a current to the first tie bar after singulating the first and second electrical terminals to electroplate the first and second electrical terminals; applying a current to the second tie bar after singulating the third electrical terminal to electroplate the third electrical terminal; singulating the first tie bar after electroplating the first and second electrical terminals; and singulating the second tie bar after electroplating the third electrical terminal. One or more such embodiments may be supplemented using one or more of the following concepts, in any order and in any combination: wherein applying said current to electroplate the first, second and third electrical terminals comprises electroplating with tin; wherein applying said current to electroplate the first, second and third electrical terminals comprises applying an electroplating thickness of at least 7 microns; wherein singulating the first, second and third electrical terminals comprises exposing flanks of said package.

At least some embodiments are directed to a package, comprising: a first singulated lead; a second singulated lead electrically isolated from the first singulated lead; a first tie bar electrically coupled to the first singulated lead and adapted for electroplating the first singulated lead; and a second tie bar electrically coupled to the second singulated lead and adapted for electroplating the second singulated lead. One or more such embodiments may be supplemented using one or more of the following concepts, in any order and in any combination: further comprising electroplating disposed on the first singulated lead, the second singulated lead, or both; wherein the first and second tie bars are singulated; wherein said electroplating comprises tin; further comprising a third singulated lead electrically coupled to the first singulated lead and electrically isolated from the second lead, said first tie bar adapted for electroplating the third singulated lead.

### BRIEF DESCRIPTION OF THE DRAWINGS

In the drawings:

FIG. 1 is a schematic diagram of a package having a lead frame.

FIG. 2 is a schematic diagram of a package having a lead frame, a die, a wire bond and a clip bond.

FIG. 3 is a schematic diagram of a package having a lead frame with singulated electrical terminals.

FIG. 4 is a schematic diagram of a package having a lead frame with electroplated electrical terminals.

FIG. 5 is a schematic diagram of a package having a lead frame with singulated tie bars.

FIG. 6 is a bottom-up view of a package having multiple, electroplated electrical terminals.

FIG. 7 is a perspective view of a package having multiple, electroplated electrical terminals and multiple, singulated tie bars.

FIG. 8 depicts a process for forming a package having electrical terminal electroplating that is resistant to migration over long periods of time.

It should be understood, however, that the specific embodiments given in the drawings and detailed description thereto do not limit the disclosure. On the contrary, they provide the foundation for one of ordinary skill to discern the alternative forms, equivalents, and modifications that are encompassed together with one or more of the given embodiments in the scope of the appended claims.

### DETAILED DESCRIPTION

Disclosed herein are various techniques for improving the longevity of plated, wettable package flanks. In at least some embodiments, a package lead frame has multiple electrical terminals (e.g., leads), and each terminal is electrically coupled—directly or indirectly—to a lead frame tie bar. The terminals are singulated as may be necessary so that the package flanks are exposed; current is applied to the tie bars to electroplate the electrical terminals to a desired thickness; and, after the electroplating process is complete and the desired plating thickness has been achieved on the terminals, the tie bars are singulated. The end result is a package that has terminals with relatively thick plating (e.g., 7 microns or more). Such thick plating mitigates long-term migration of the electroplating material (e.g., tin) into the terminals and is thus conducive to long-term wettability and a relatively long shelf life for the packages.

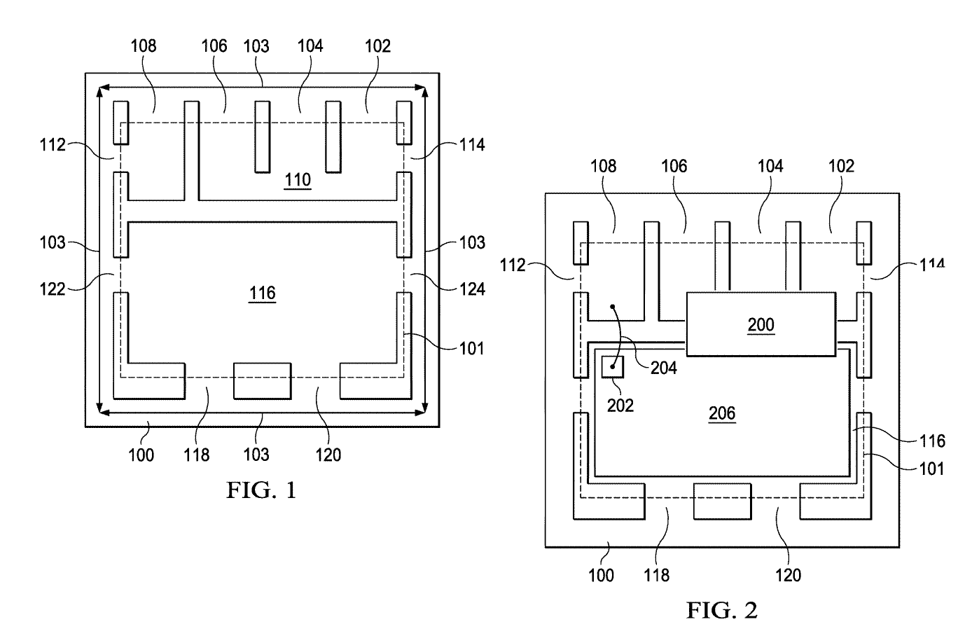

FIG. 1 is a schematic diagram of a package having a lead frame 100. The lead frame 100 may be part of a larger lead frame strip (not expressly shown). The lead frame 100 has a dam bar 103 that generally includes the rectangular periphery of the lead frame 100. The dam bar 103 couples to electrical terminals (e.g., leads) 102, 104, 106, 108, 118, and 120. The electrical terminals 102, 104, and 106 electrically couple to each other, as numeral 110 indicates. Electrical terminal 108 is electrically isolated from the remaining terminals. Electrical terminals 118 and 120 electrically couple to the electrical terminals 102, 104, and 106 via a die that is mounted on die flag 116 (die expressly shown in FIG. 2). The dam bar 103 electrically couples to the electrical terminal 108 via tie bar 112; to electrical terminals 102, 104, and 106 via tie bar 114; and to die flag 116 via tie bars 122 and 124 and electrical terminals 118 and 120. The various components of the lead frame 100—i.e., the dam bar 103, the tie bars 112, 114, 122, 124, the electrical terminals 102, 104, 106, 108, 118, and 120, and the die flag 116—all are preferably composed of the same or similar electrically conductive material, such as copper or a copper alloy. Numeral 101 references the outline of a package that incorporates multiple portions of the lead frame 100.

The design of lead frame 100 depicted in the figures is merely illustrative. The techniques described herein are not limited to application in lead frames having a design similar or identical to that shown in the figures. On the contrary, the disclosed techniques may be applied to any and all suitable package lead frames that may benefit from flank plating that is resistant to migration. For instance and without limitation, in some embodiments, the electrical terminals of lead frame 100 may all be electrically coupled to each other. In some embodiments, some electrical terminals may electrically couple to each other while other electrical terminals are isolated. In some embodiments, multiple groups of inter-connected electrical terminals may be formed, but the groups may be electrically isolated from each other. Any and all such variations and combinations are included in the scope of this disclosure. In preferred embodiments, however, each electrical terminal to be plated couples either directly or indirectly to at least one tie bar. For example, as shown in illustrative FIG. 2, although the electrical terminal 108 is isolated from all other electrical terminals, it electrically couples to the tie bar 112. Similarly, the electrical terminals 102, 104, and 106 electrically couple to the tie bar 114. Likewise, the electrical terminals 118 and 120 electrically couple to the tie bar 114 via the die 206, clip 200, and electrical terminal 114. As explained below, ensuring that each electrical terminal to be plated electrically couples to a tie bar enables proper plating.

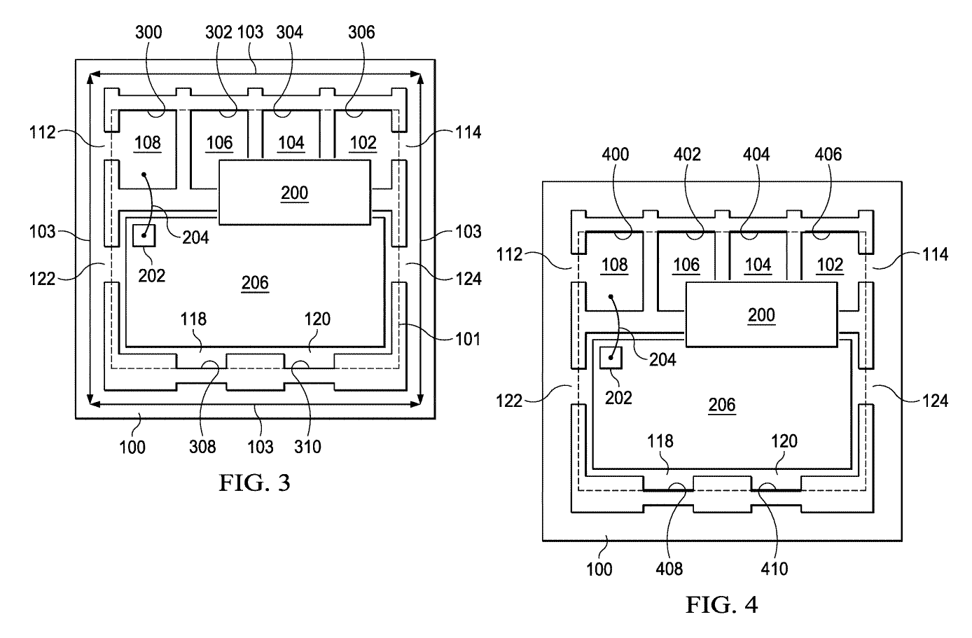

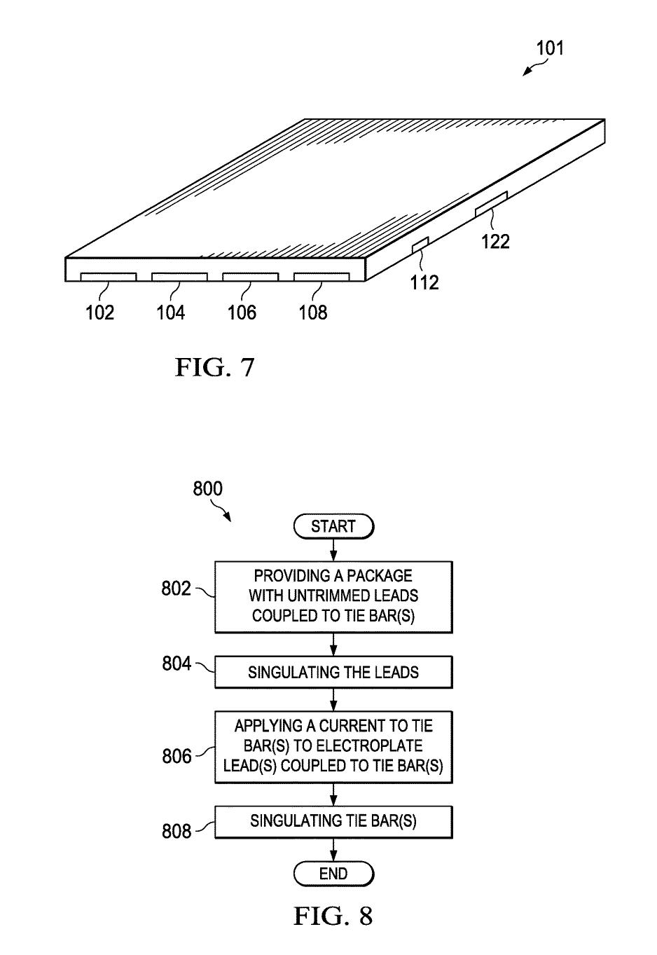

FIG. 2 is a schematic diagram of a package having a lead frame 100 as described with reference to FIG. 1; a die 206 mounted upon the die flag 116; a wire bond 204 electrically coupling the electrical terminal 108 to the die 206 via bond pad 202; and a clip bond 200 electrically coupling the electrical terminals 102, 104, and 106 to the die 206. The electrical terminal 108 is electrically coupled to the die 206 but is electrically isolated from the remaining electrical terminals 102, 104, 106, 118, and 120. Other techniques for electrically coupling the various electrical terminals to the die 206 are contemplated and included within the scope of this disclosure. FIGS. 3-5 depict a sequence of steps for processing the package of FIG. 2 so that the electrical terminals of the package are resistant to migration and promote long-term wettability. FIGS. 6 and 7 depict the end product resulting from the steps shown in FIGS. 3-5.

FIG. 3 is a schematic diagram of the package having singulated electrical terminals. Specifically, the electrical terminals 102, 104, 106, 108, 118, and 120 all have been singulated (as indicated by numerals 306, 304, 302, 300, 308, and 310, respectively) so that the corresponding flanks are exposed on the side surfaces of the package 101 (i.e., the ends of the electrical terminals are flush with the side surfaces of the package 101, where “flush” means that the electrical terminals extend beyond the package surfaces by no more than 2 mm or the electrical terminals are recessed within the package surfaces by no more than 2 mm). Any suitable technique may be employed to achieve such electrical terminal singulation, including punching and sawing techniques. Regardless of the precise technique used, the singulation should achieve complete electrical and physical separation between the electrical terminals and the dam bar 103. Once this singulation of the electrical terminals has been performed, the electrical terminals couple to the dam bar 103 only via the tie bars 112, 114, 122, and 124.

FIG. 4 is a schematic diagram of the package having electroplated electrical terminals. Specifically, as numerals 400, 402, 404, 406, 408, and 410 and the corresponding bold lines indicate, each of the electrical terminals 108, 106, 104, 102, 118, and 120 is electroplated with any suitable material, such as tin. The electrical terminals are electroplated by passing current through the terminals while using an appropriate electroplating solution; however, as one skilled in the art would recognize, current is not directly applied to the terminals to be plated. Accordingly, the electrical terminals 102, 104, 106, 108, 118, and 120 may be electroplated by applying current to the tie bars 112 and 114. In particular, the tie bar 112 electrically couples to the electrical terminal 108, so applying a suitable current to the tie bar 112 (in tandem with an appropriate electroplating solution through which the current may pass) causes the flank—that is, the portion of the electrical terminal 108 exposed outside the package 101—to be electroplated, as numeral 400 indicates. The electroplating technique may be used to achieve any desired plating thickness. In at least some embodiments, the plating thickness is at least 7 microns. Similarly, the tie bar 114 electrically couples to the electrical terminals 102, 104, 106, 118, and 120, so applying a suitable current to the tie bar 114 (in tandem with an appropriate electroplating solution through which the current may pass) causes the flanks—i.e., the portions of the electrical terminals 102, 104, 106, 118, and 120 exposed outside the package 101—to be electroplated, as numerals 406, 404, 402, 408, and 410 indicate. The electroplating technique may be used to achieve any desired plating thickness. In at least some embodiments, the plating thickness is at least 7 microns.

In at least some embodiments, the tie bars 112, 114 remain physically and/or electrically coupled to the electrical terminals until the electroplating process is complete. In some embodiments, the tie bars 112, 114 are removed simultaneously—that is, after all electrical terminals to which the tie bars couple have been electroplated. In other embodiments, each of the tie bars 112, 114 is removed as soon as the corresponding electrical terminals have been plated, meaning that the tie bars are removed at different times. Removal (i.e., singulation) of the tie bars 112, 114 may be accomplished by any suitable technique, such as by sawing or punching.

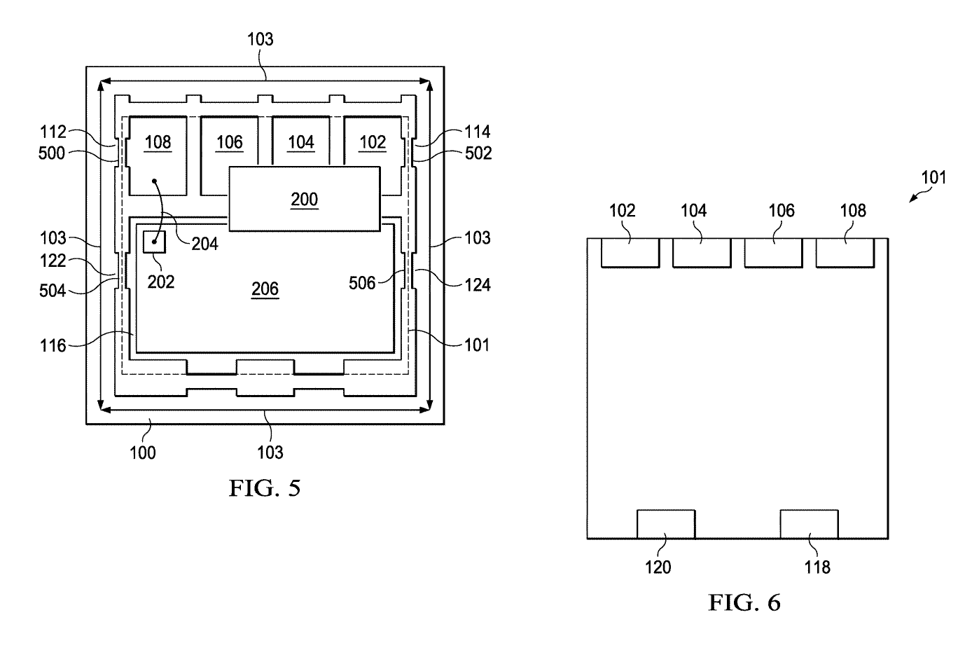

FIG. 5 depicts a schematic diagram of the lead frame 100 with tie bars that have been singulated after electroplating of the electrical terminal flanks. As numeral 500 indicates, for instance, the tie bar 112 is singulated so that the electrical terminal 108 is no longer coupled to the dam bar 103. The tie bar 112 is singulated after the electrical terminal 108 is electroplated to the desired thickness. Similarly, numeral 502 indicates that the tie bar 114 is singulated so that the electrical terminals 102, 104, and 106 are no longer coupled to the dam bar 103. The tie bar 114 is singulated after the electrical terminals 102, 104, and 106 are electroplated to the desired thicknesses. The tie bar 122 is singulated as numeral 504 indicates, and, as numeral 506 indicates, tie bar 124 is also singulated. In this particular example, the tie bars 122 and 124 are not used to electroplate electrical terminals; they are used to mechanically support the die flag 116. Thus, the tie bars 122, 124 may be singulated when such physical support is no longer necessary.

FIG. 6 is a bottom-up view of the package 101 having multiple electroplated electrical terminals. Specifically, the underside of the package 101 shows the electrical terminals 102, 104, 106, 108, 118, and 120 electroplated and exposed. These electrical terminals are electroplated to a desired thickness (e.g., at least 7 microns) with tin or some other suitable material. In some embodiments, the outer surfaces of these electrical terminals are flush (i.e., within +/−2 mm) with the surfaces of the package 101 prior to electroplating. In some embodiments, the outer surfaces of these electrical terminals are flush with the surfaces of the package 101 after electroplating. In some embodiments, the outer surfaces of these electrical terminals are not ever flush with the surfaces of the package 101. Any and all such variations are contemplated. FIG. 7 is a perspective view of the package 101. This view shows the positions of the tie bars 112 and 122 after singulation. In at least some embodiments, the exposed surfaces of the tie bars 112 and 122 are flush with the surface of the package 101.

FIG. 8 depicts an illustrative process 800 for forming a package having terminal electroplating that is resistant to migration. The process 800 begins by providing a package with untrimmed electrical terminals coupled to tie bars (step 802). As explained above, various permutations of this arrangement are possible. For instance and without limitation, some electrical terminals may be isolated from other electrical terminals, and some electrical terminals may be electrically coupled to other electrical terminals. The process 800 continues by singulating the electrical terminals to expose the flanks—i.e., to make the outer surfaces of the electrical terminals flush with the surfaces of the package in which they are housed (step 804). As explained, in some embodiments, exposing the flanks may comprise singulating the electrical terminals so that they are flush with the package surfaces after electroplating is complete. The process 800 next comprises applying a current to the tie bars to electroplate the electrical terminals coupled to the tie bars using an appropriate electroplating solution (step 806). After the electrical terminals are electroplated to desired thicknesses, the process 800 comprises singulating the tie bars so that they are flush with the corresponding surfaces of the package (step 808). The process 800 is then complete. The process 800 may be modified as desired, including by adding, deleting, modifying, or rearranging one or more steps.

Numerous other modifications, equivalents, and alternatives, will become apparent to those skilled in the art once the above disclosure is fully appreciated. It is intended that the following claims be interpreted to embrace all such modifications, equivalents, and alternatives where applicable.

1. A method for plating package leads, comprising:
providing a package having a lead electrically coupled to one or more tie bars;
singulating said lead;
electroplating said singulated lead by passing a current from a lead frame to the singulated lead solely via the one or more tie bars; and
singulating said one or more tie bars.

2. The method of claim 1, wherein singulating the lead comprises causing an end of the lead to be flush with a side surface of the package.

3. The method of claim 1, wherein singulating the lead comprises punching.

4. The method of claim 1, wherein singulating the lead comprises sawing.

5. The method of claim 1, wherein said electroplating comprises electroplating the lead with tin.

6. The method of claim 1, wherein said electroplating results in said lead having a plating at least 7 microns thick.

7. (canceled)

8. The method of claim 1, wherein passing said current via the one or more tie bars results in another lead of the package being electroplated, said lead and the another lead electrically coupled to each other.

9. The method of claim 1, wherein providing the package comprises electrically coupling said lead to said one or more tie bars.

10. The method of claim 1, wherein said package comprises a second lead and a third lead, and wherein passing said current via the one or more tie bars to electroplate the lead also results in electroplating the second lead but not the third lead.

11. The method of claim 10, further comprising applying another current to a second tie bar coupled to the third lead to electroplate the third lead.

12. A method, comprising:
providing a package having first, second and third electrical terminals, said first and second electrical terminals electrically coupled to each other and to a first tie bar, said third electrical terminal electrically coupled to a second tie bar;
singulating the first, second and third electrical terminals;
passing a current from a lead frame to the first and second electrical terminals solely via the first tie bar after singulating the first and second electrical terminals to electroplate the first and second electrical terminals;
passing another current from the lead frame to the third electrical terminal solely via the second tie bar after singulating the third electrical terminal to electroplate the third electrical terminal;
singulating the first tie bar after electroplating the first and second electrical terminals; and
singulating the second tie bar after electroplating the third electrical terminal.

13. The method of claim 12, wherein passing said current and said another current to electroplate the first, second and third electrical terminals comprises electroplating with tin.

14. The method of claim 12, wherein passing said current and said another current to electroplate the first, second and third electrical terminals comprises applying an electroplating thickness of at least 7 microns.

15. The method of claim 12, wherein singulating the first, second and third electrical terminals comprises exposing flanks of said package.

16. A package, comprising:
a first singulated lead;
a second singulated lead electrically isolated from the first singulated lead;
a first tie bar electrically coupled to the first singulated lead and adapted for electroplating the first singulated lead; and
a second tie bar electrically coupled to the second singulated lead and adapted for electroplating the second singulated lead.

17. The package of claim 16, further comprising electroplating disposed on the first singulated lead, the second singulated lead, or both.

18. The package of claim 17, wherein the first and second tie bars are singulated.

19. The package of claim 17, wherein said electroplating comprises tin.

20. The package of claim 16, further comprising a third singulated lead electrically coupled to the first singulated lead and electrically isolated from the second lead, said first tie bar adapted for electroplating the third singulated lead.
